(19) United States
(12) Patent Application Publication
(10) Pub. No.: US 2019/0103533 A1
(43) Pub. Date: Apr. 4, 2019

(54) METAL-CERAMIC COMPOSITE LEAD FRAME STRUCTURE, MANUFACTURING METHOD THEREOF, AND LED USING THE SAME STRUCTURE

(71) Applicant: YI-JHEN LEE, Mingjian Township (TW)

(72) Inventor: YI-JHEN LEE, Mingjian Township (TW)

(21) Appl. No.: 16/141,309

(22) Filed: Sep. 25, 2018

(30) Foreign Application Priority Data
Sep. 29, 2017 (TW) 106133719

(51) Int. Cl. H01L 33/62

(52) U.S. Cl. CPC H01L 33/62; H01L 23/49582

(57) ABSTRACT

The present invention provides a metal-ceramic lead frame structure, a manufacturing method thereof, and a LED by using the same structure. The metal-ceramic lead frame structure of the present invention includes a substrate. The substrate comprises a metal base layer and a ceramic layer provided on an exterior of the metal base layer, and the substrate has a plurality of chip carriers integrally formed with the substrate by machining the substrate.

### BACKGROUND OF THE INVENTION

### 1. Technical Field

The present invention relates to a lead frame structure of which lead frames are made. More particularly, the invention relates to a metal-ceramic composite lead frame structure for use in the manufacture of light-emitting diodes (LEDs).

### 2. Description of Related Art

Nowadays, LEDs can be built on such heat dissipation substrates as printed circuit boards (PCBs), metal core PCBs (MCPCBs), and ceramic substrates, of which PCBs are the earliest in use.

The mainstream of heat dissipation substrates on market, however, are MCPCBs, which are printed circuit boards with a metal substrate, or core. More specifically, an MCPCB is a PCB attached to a metal base layer in order for the metal (e.g., aluminum or copper) to provide enhanced thermal conduction and efficient heat dissipation. A common single-sided aluminum substrate structure is composed of a copper foil, an insulating layer, and an aluminum plate. As the insulating layer of a typical MCPCB is formed of resin, there is a temperature limit (generally 140° C.) in use. If subjected repeatedly to high temperature during the manufacturing process or during use, the resin insulating layer may crack or even peel off.

To address the issues of heat dissipation and cracked insulating layers, ceramic substrates were developed recently. Ceramic is a good heat dissipation material because it has not only consistent performance in a high-temperature and high-humidity environment, but also considerable resistance to heat and superior thermal conductivity. Recently, ceramic substrates used for metal line configuration include a low-temperature co-fired ceramic (LTCC) and a high-temperature co-fired ceramic (HTCC).

### BRIEF SUMMARY OF THE INVENTION

Indeed, ceramic substrates help improve heat dissipation, can dispense with an epoxy resin insulating layer, but are disadvantaged by the exceedingly high melting point and hardness of ceramic, which impose limitations on the machinability of such substrates. Ceramic substrates also incur relatively high material cost and production cost. Moreover, whether an MCPCB or ceramic substrate is used as the lead frame of an LED, the manufacturing process of the LED requires a cup (also known as a barrier, wall, or reflector cup) to be additionally provided in order to form the chip carrier, and yet the provision of the cup results in an extra step. For example, it is common practice to attach the cup adhesively to the substrate via an epoxy resin adhesive.

To address the above problems, the present invention provides a metal-ceramic composite lead frame structure, comprising a substrate, wherein the substrate comprises a metal base layer and a ceramic layer provided on an exterior of the metal base layer, and the substrate has a plurality of chip carriers integrally formed with the substrate by machining the substrate.

Furthermore, the substrate is machined to form at least one slit around a periphery of each said chip carrier, and each said chip carrier is connected to the substrate by at least one connection unit adjoining or between the at least one slit around the each said chip carrier.

Furthermore, the chip carriers comprise closed protruding units formed by stamping.

Furthermore, each said chip carrier has at least one through hole and at least one conductive connection unit provided respectively in the at least one through hole.

Furthermore, at least one metal line is provided on the ceramic layer of the chip carrier and is connected to the chip on the chip carrier.

In addition, the present invention provides a method for manufacturing a metal-ceramic composite strip lead frame, including the steps of: providing a metal base layer, forming a ceramic layer on the surface of the metal base layer, and stamping the metal base layer to from an array of protruding units, wherein the protruding units surround and form a plurality of closed spaces there between, and the closed spaces serve respectively as chip carriers and are to be filled with an encapsulant.

Furthermore, the above method further includes a step of forming a plurality of slits by cutting the metal base layer according to the array of protruding units to be formed, leaving at least one connection unit for each protruding unit in order for the metal base layer to support the chip carriers.

Furthermore, each said chip carrier has at least one through hole, each said through hole is provided therein with the ceramic layer that coats the wall surface of each said through hole, and the least one through hole is further provided therein with at least one conductive connection unit respectively.

Furthermore, at least one metal line provided on the ceramic layer of the chip carrier and connected to the chip on the chip carrier.

In addition, the present invention provides a light-emitting diode, comprising the above metal-ceramic composite lead frame structure of the present invention.

As above, comparing to the conventional techniques, the present invention has the following advantages:

1. The present invention provides a metal-ceramic composite lead frame structure and its manufacturing method. In contrast to the conventional MCPCBs and ceramic substrates, both of which require the use of adhesive (e.g., an epoxy resin adhesive) in the LED manufacturing process so as to mount a cup (also known as a barrier, wall, or reflector cup) and thereby form the chip carrier, the lead frame structure of the present invention is integrally formed, by stamping, with closed protruding structures that make up chip carriers; consequently, the resulting LED manufacturing process is simpler and incurs lower cost than the conventional ones. Also, the lead frame structure of the present invention eliminates the use of adhesive or other curable plastic material, thereby avoiding such problems as the cup peeling off the substrate due to deterioration of the adhesive (e.g., yellowing and embrittling under repeated exposure to high temperature).

2. The metal-ceramic composite lead frame structure of the present invention and its manufacturing method employ a metal base layer, rather than a ceramic one, as the core of the substrate. Thus, not only can material cost be reduced, but also the metal base layer advantageously provides efficient dissipation of heat, as well as high mechanical strength during the substrate machining process.

3. The lead frame structure of the present invention can be used to package LED chips of a horizontal chip configuration, a vertical chip configuration, or a flip-chip configuration without limitation.

### BRIEF DESCRIPTION OF THE SEVERAL VIEWS OF THE DRAWINGS

FIG. 1(a) and FIG. 1(b) are respectively a perspective view and a sectional view of the metal-ceramic composite lead frame structure according to the first embodiment of the present invention;

FIG. 2 shows sectional views that illustrate the manufacturing method of the metal-ceramic composite lead frame structure according to the first embodiment of the invention;

FIG. 3 shows sectional views that illustrate the manufacturing method of LEDs based on the first embodiment of the invention;

FIG. 4(a) and FIG. 4(b) show LEDs based on the first embodiment of the invention, with FIG. 4(a) being a perspective view of the metal-ceramic composite lead frame structure in the packaged state, and FIG. 4(b) being a perspective view of one of the LEDs;

FIG. 5 is a perspective view of the metal-ceramic composite lead frame structure according to the second embodiment of the invention;

FIG. 6(a), FIG. 6(b), and FIG. 6(c) show the manufacturing method of the metal-ceramic composite lead frame structure according to the second embodiment of the invention, with FIG. 6(a) in perspective view, FIG. 6(b) in top view, and FIG. 6(c) in sectional view;

FIG. 7(a), FIG. 7(b), and FIG. 7(c) show the manufacturing method of LEDs based on the second embodiment of the invention, with FIG. 7(a) in perspective view, FIG. 7(b) in top view, and FIG. 7(c) in sectional view; and

FIG. 8(a) and FIG. 8(b) show LEDs based on the second embodiment of the invention, with FIG. 8(a) being a perspective view of the metal-ceramic composite lead frame structure in the packaged state, and FIG. 8(b) being a perspective view of one of the LEDs.

### DETAILED DESCRIPTION OF THE INVENTION

The details and technical solution of the present invention are hereunder described with reference to accompanying drawings. For illustrative sake, the accompanying drawings are not drawn to scale, amount, and shape. The accompanying drawings and the scale, amount, and shape thereof are restrictive of the present invention.

The present invention provides a metal-ceramic composite strip lead frame structure, a method for manufacturing the metal-ceramic composite strip lead frame structure and LED comprising the same.

The metal-ceramic composite strip lead frame structure comprises a substrate, wherein the substrate comprises a metal base layer and a ceramic layer provided on an exterior of the metal base layer, and the substrate has a plurality of chip carriers integrally formed with the substrate by machining the substrate.

The method includes the steps of: providing a metal base layer, forming a ceramic layer on the surface of the metal base layer, and stamping the metal base layer to from an array of protruding units, wherein the protruding units surround and form a plurality of closed spaces therebetween, and the closed spaces serve respectively as chip carriers and are to be filled with an encapsulant.

Each of the chip carriers is provided with a conductive connection means to bring the chip on the chip carrier into conductive connection with signals outside the chip carrier, in order for the chip to emit light upon establishment of such connection. The conductive connection means of each chip carrier may be at least one through hole in the chip carrier and at least one conductive connection unit provided respectively in the at least one through hole, or at least one metal line provided on the ceramic layer of the chip carrier and connected to the chip on the chip carrier.

As used herein, the term “metal base layer” refers to copper, aluminum, a copper alloy, or an aluminum alloy. For example, the copper alloy may be, but is not limited to, a copper-zinc alloy, a copper-tin alloy, a copper-aluminum alloy, a copper-silicon alloy, or a copper-nickel alloy; and the aluminum alloy may be, but is not limited to, an aluminum-silicon alloy, an aluminum-magnesium-silicon alloy, an aluminum-copper alloy, an aluminum-magnesium alloy, an aluminum-manganese alloy, an aluminum-zinc alloy, or an aluminum-lithium alloy. Preferably, the metal base layer is aluminum, an aluminum alloy, copper, or a copper alloy.

As used herein, the term “ceramic layer” refers to a common ceramic material, which includes various metal oxides, carbides, nitrides, borides, silicides, and combinations of the above. For example, the ceramic material may be, but is not limited to, SiC, Si₃N₄, AlN, Al₂O₃, TiC, TiB₂ or B₄C. Preferably, the ceramic layer is Al₂O₃, Si₃N₄, or AlN because of the excellent heat conductivity and small thermal expansion coefficient. The ceramic layer is formed by a common ceramic-metal composite forming method, including but not limited to coating, anodizing, micro-arc oxidation, plasma electrolytic oxidation, magnetron sputtering, and a sol-gel process. The ceramic layer has a thickness of 10 μm˜900 μm, preferably 20 μm˜200 μm, more preferably 30 μm˜50 μm. A ceramic layer whose thickness falls into any of the foregoing ranges is not prone to embrittlement but flexible and can withstand the stamping force applied during the substrate machining process. The ceramic layer may also be rendered reflective by a mirror surface finish.

As used herein, the terms “conductive connection unit” and “metal line” refer to any electrically conductive material, including metals, alloys, and composite metals, such as but not limited to silver, copper, gold, aluminum, sodium, molybdenum, tungsten, zinc, nickel, iron, platinum, tin, lead, a silver-copper alloy, a cadmium-copper alloy, a chromium-copper alloy, a beryllium-copper alloy, a zirconium-copper alloy, an aluminum-magnesium-silicon alloy, an aluminum-magnesium alloy, an aluminum-magnesium-iron alloy, an aluminum-zirconium alloy, an iron-chromium-aluminum alloy, silicon carbide, and graphite.

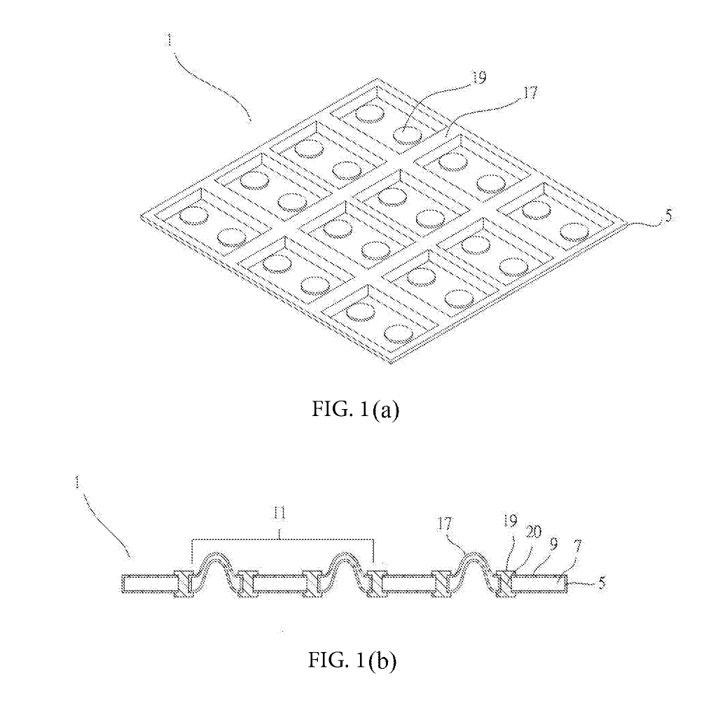

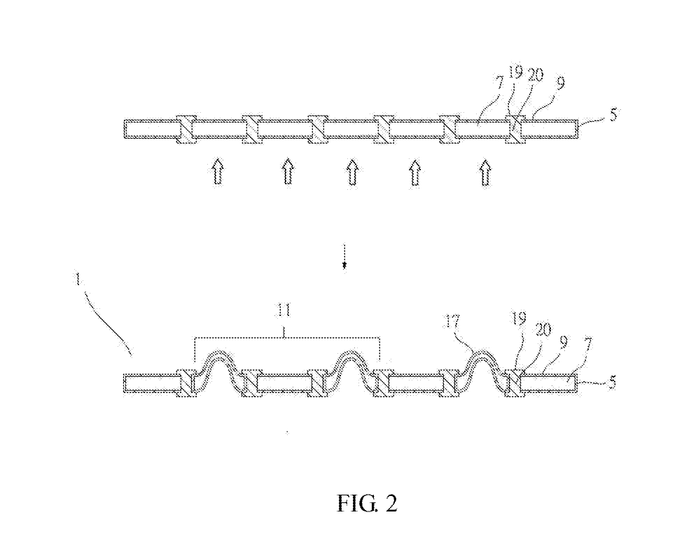

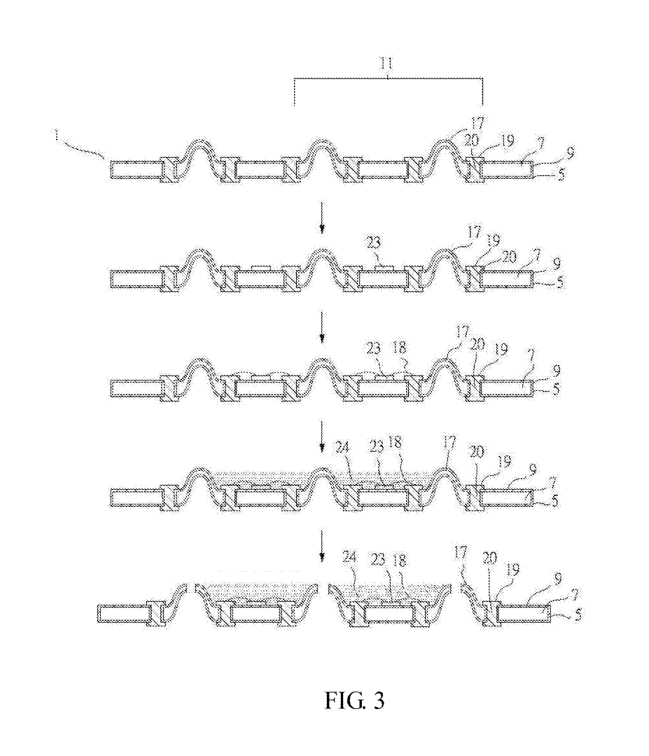

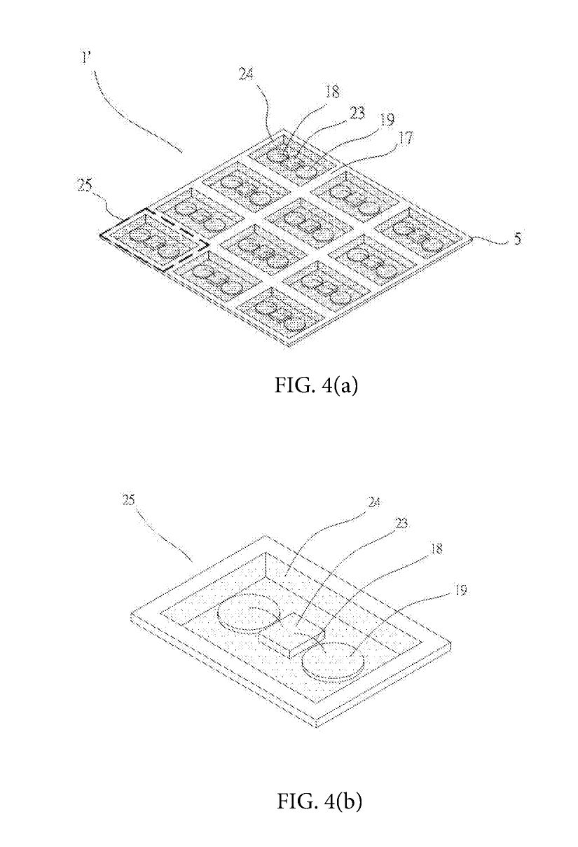

Hereinafter, the first embodiment of the present invention is described with reference to FIG. 1, FIG. 2, FIG. 3, and FIG. 4. In this embodiment, the conductive connection means of each chip carrier is “at least one through hole in the chip carrier and at least one conductive connection unit provided respectively in the at least one through hole” by way of example. In practice, the conductive connection means of each chip carrier is not limited to those shown in the drawings and may alternatively be “at least one metal line provided on the ceramic layer of the chip carrier and connected to the chip on the chip carrier”.

FIG. 1(a) and FIG. 1(b) are respectively a perspective view and a sectional view of the metal-ceramic composite lead frame structure according to the first embodiment of the invention. In this embodiment, the metal-ceramic composite lead frame structure 1 includes a substrate 5, and the substrate 5 includes a metal base layer 7 and a ceramic layer 9 provided on the exterior of the metal base layer 7. The substrate 5 also has a plurality of chip carriers 11, which are integrally formed with the substrate 5 by machining the substrate 5.

FIG. 2 shows sectional views that illustrate the manufacturing method of the metal-ceramic composite lead frame structure according to the first embodiment of the invention. The method for manufacturing the metal-ceramic composite lead frame of this embodiment includes: step 1) providing a metal base layer 7; step 2) forming a ceramic layer 9 on the surface of the metal base layer 7; and step 3) stamping the metal base layer 7 to form an array of protruding units 17, wherein the protruding units 17 surround and form a plurality of closed spaces therebetween, and the closed spaces serve as a plurality of chip carriers 11 respectively and are to be filled with an encapsulant. Please note that the order of steps 2 and 3 may be reversed.

Each chip carrier 11 has at least one through hole 20. Each through hole 20 is provided therein with the ceramic layer 9, which coats the wall surface of the through hole 20, and the at least one through hole 20 is further provided therein with at least one conductive connection unit 19 respectively. Alternatively, the chip carriers 11 may be so designed that at least one metal line is provided on the ceramic layer 9 of each chip carrier 11 and is connected to the chip on the chip carrier 11. The conductive connection units 19 or metal lines may be provided in/on the chip carriers 11 after step 2 or 3 without limitation.

FIG. 3 shows sectional views that illustrate the manufacturing method of LEDs based on the first embodiment of the invention. FIG. 4(a) and FIG. 4(b) are respectively a perspective view showing the metal-ceramic composite lead frame structure of the first embodiment of the invention after it is packaged, and a perspective view of an LED based on the first embodiment of the invention. As shown in FIG. 3, LEDs based on this embodiment are manufactured with the metal-ceramic composite lead frame structure 1 according to the first embodiment of the invention, or more specifically by providing each chip carrier 11 with a chip 23 and the necessary wires 18, packaging each chip carrier 11 with an encapsulant 24, and then cutting the metal-ceramic composite lead frame structure 1 to singulate the LEDs. FIG. 4(a) shows the packaged metal-ceramic composite lead frame structure 1′, which has a plurality of LEDs 25 that have yet to be singulated. FIG. 4(b) shows an LED 25 that has been singulated by cutting the packaged metal-ceramic composite lead frame structure 1′.

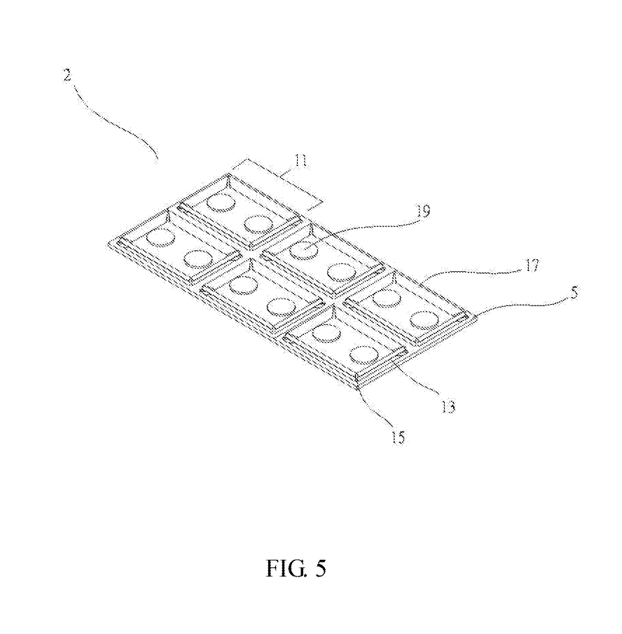

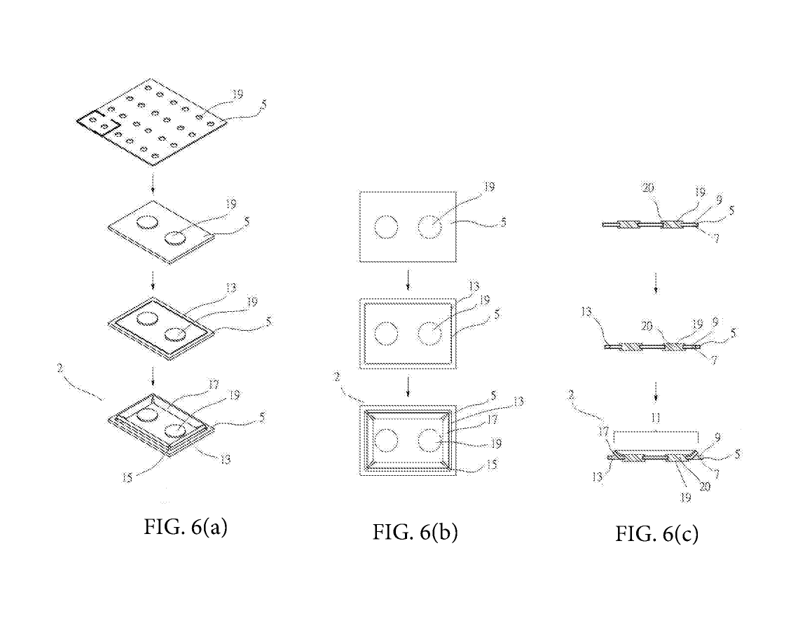

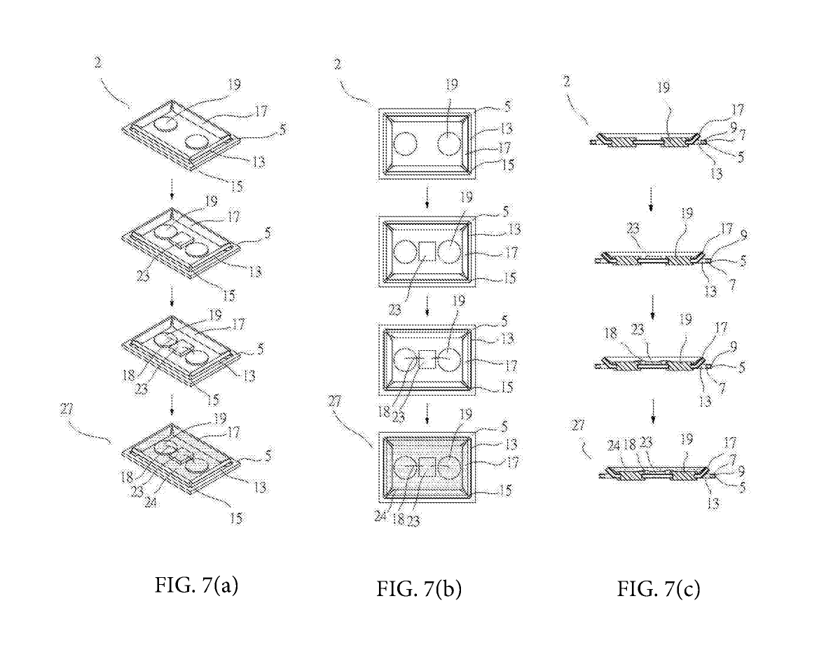

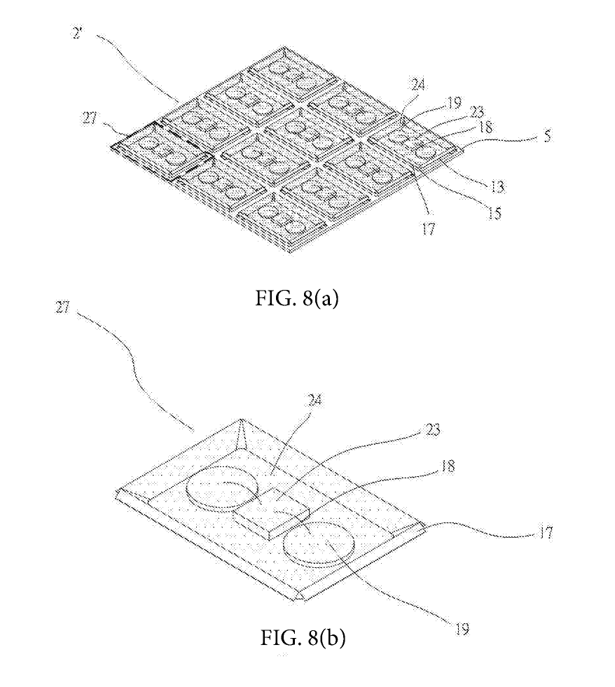

The second embodiment of the present invention is described below with reference to FIG. 5, FIG. 6, FIG. 7, and FIG. 8. In this embodiment, the conductive connection means of each chip carrier is “at least one through hole in the chip carrier and at least one conductive connection unit provided respectively in the at least one through hole” by way of example. In practice, the conductive connection means of each chip carrier is not limited to those shown in the drawings and may alternatively be “at least one metal line provided on the ceramic layer of the chip carrier and connected to the chip on the chip carrier”.

FIG. 5 is a perspective view of the metal-ceramic composite lead frame structure according to the second embodiment of the invention. In this embodiment, the metal-ceramic composite lead frame structure 2 includes a substrate 5, and the substrate 5 includes a metal base layer and a ceramic layer provided on the exterior of the metal base layer. The substrate 5 also has a plurality of chip carriers 11, which are integrally formed with the substrate 5 by machining the substrate 5, wherein the “machining” process further includes forming at least one slit 13 around the periphery of each chip carrier 11 such that each chip carrier 11 is connected to the substrate 5 by at least one connection unit 15 that adjoins or lies between the at least one slit 13.

FIG. 6(a), FIG. 6(b), and FIG. 6(c) show the manufacturing method of the metal-ceramic composite lead frame structure according to the second embodiment of the invention, with FIG. 6(a) in perspective view, FIG. 6(b) in top view, and. FIG. 6(c) in sectional view. The method for manufacturing the metal-ceramic composite lead frame of this embodiment includes: step 1) providing a metal base layer 7; step 2) forming a ceramic layer 9 on the surface of the metal base layer 7 (to form the substrate 5 in FIG. 6(c)); step 3) forming a plurality of slits 13 by cutting the metal base layer 7 according to the array of protruding units 17 to be formed, leaving at least one connection unit 15 for each protruding unit 17 in order for the metal base layer 7 to support the chip carriers 11 in the following stamping step; and step 4) stamping the metal base layer 7 to form the array of protruding units 17, wherein the protruding units 17 surround and form a plurality of closed spaces therebetween, and the closed spaces serve as a plurality of chip carriers 11 respectively and are to be filled with an encapsulant. Please note that the order of steps 2 and 3 may also be reversed.

Each chip carrier 11 has at least one through hole. Each through hole is provided therein with the ceramic layer, which coats the wall surface of the through hole, and the at least one through hole is further provided therein with at least one conductive connection unit 19 respectively. Alternatively, the chip carriers 11 may be so designed that at least one metal line is provided on the ceramic layer of each chip carrier 11 and is connected to the chip on the chip carrier 11. The conductive connection units 19 or metal lines may be provided in/on the chip carriers 11 after step 2 or 4 without limitation.

FIG. 7(a), FIG. 7(b), and FIG. 7(c) show the manufacturing method of LEDs based on the second embodiment of the invention, with FIG. 7(a) in perspective view, FIG. 7(b) in top view, and FIG. 7(c) in sectional view. FIG. 8(a) and FIG. 8(b) are respectively a perspective view showing the metal-ceramic composite lead frame structure of the second embodiment of the present invention after it is packaged, and a perspective view of an LED based on the second embodiment of the invention. As shown in FIG. 7(a), FIG. 7(b), and FIG. 7(c), LEDs based on this embodiment are manufactured with the metal-ceramic composite lead frame structure 2 according to the second embodiment of the invention, or more specifically by providing each chip carrier with a chip 23 and the necessary wires 18, packaging each chip carrier with an encapsulant 24, and then cutting the connection units 15 to singulate the LEDs. FIG. 8(a) shows the packaged metal-ceramic composite lead frame structure 2′, which has a plurality of LEDs 27 that have yet to be singulated. FIG. 8(b) shows an LED 27 that has been singulated by cutting the corresponding connection units 15 on the packaged metal-ceramic composite lead frame structure 2′.

The metal-ceramic composite lead frame structure of the present invention is highly adaptable and can be mounted with a horizontal chip, a vertical chip, or a flip chip without limitation. While the accompanying drawings show horizontal chips by way of example, it is equally feasible to use vertical chips or flip chips instead.

According to the above, the metal-ceramic composite lead frame structure of the present invention can dissipate heat more efficiently and is more flexible than its conventional counterparts. By the same token, LEDs manufactured with the metal-ceramic composite lead frame structure of the present invention can dissipate heat more efficiently and are more flexible than their conventional counterparts. Furthermore, LEDs based on the present invention do not have issues associated with the adhesive in the conventional LEDs (i.e., the adhesive between each cup (also known as barrier, wall, or reflector cup) and the substrate tends to yellow and embrittle when subjected to high temperature repeatedly) and are therefore more adaptable than their conventional counterparts and suitable for use in various electronic devices and environments. In addition, the method of the present invention for manufacturing a metal-ceramic composite lead frame structure has fewer steps than the existing methods, does not rely on adhesive (e.g., an epoxy resin adhesive) for the provision of cups (also known as barriers, walls, or reflector cups), and hence incurs lower material cost and production cost than its conventional counterparts.

While the present invention has been described in connection with certain exemplary embodiments, it is to be understood that the invention is not limited to the disclosed embodiments, but, on the contrary, intended to cover various modifications and equivalent arrangements included within the spirit and scope of the appended claims and equivalents thereof.

What is claimed is:

1. A metal-ceramic composite lead frame structure, comprising a substrate, wherein the substrate comprises a metal base layer and a ceramic layer provided on an exterior of the metal base layer, and the substrate has a plurality of chip carriers integrally formed with the substrate by machining the substrate.

2. The metal-ceramic composite lead frame structure of claim 1, wherein the substrate is machined to form at least one slit around a periphery of each said chip carrier, and each said chip carrier is connected to the substrate by at least one connection unit adjoining or between the at least one slit around the each said chip carrier.

3. The metal-ceramic composite lead frame structure of claim 1, wherein the chip carriers comprise closed protruding units formed by stamping.

4. The metal-ceramic composite lead frame structure of claim 2, wherein the chip carriers comprise closed protruding units formed by stamping.

5. The metal-ceramic composite lead frame structure of claim 1, wherein each said chip carrier has at least one through hole and at least one conductive connection unit provided respectively in the at least one through hole.

6. The metal-ceramic composite lead frame structure of claim 2, wherein each said chip carrier has at least one through hole and at least one conductive connection unit provided respectively in the at least one through hole.

7. The metal-ceramic composite lead frame structure of claim 1, wherein at least one metal line is provided on the ceramic layer of the chip carrier and is connected to the chip on the chip carrier.

8. The metal-ceramic composite lead frame structure of claim 2, wherein at least one metal line is provided on the ceramic layer of the chip carrier and is connected to the chip on the chip carrier.

9. A method for manufacturing a metal-ceramic composite strip lead frame, including the steps of:
providing a metal base layer;
forming a ceramic layer on the surface of the metal base layer; and,
stamping the metal base layer to form an array of protruding units, wherein the protruding units surround and form a plurality of closed spaces there between, and the closed spaces serve respectively as chip carriers and are to be filled with an encapsulant.

10. The method for manufacturing a metal-ceramic composite strip lead frame of claim 9, further including a step of forming a plurality of slits by cutting the metal base layer according to the array of protruding units to be formed, leaving at least one connection unit for each protruding unit in order for the metal base layer to support the chip carriers.

11. The method for manufacturing a metal-ceramic composite strip lead frame of claim 9, wherein each said chip carrier has at least one through hole, each through hole is provided therein with the ceramic layer which coats the wall surface of the through hole, and the at least one through hole is further provided therein with at least one conductive connection unit respectively.

12. The method for manufacturing a metal-ceramic composite strip lead frame of claim 10, wherein each said chip carrier has at least one through hole, each through hole is provided therein with the ceramic layer which coats the wall surface of the through hole, and the at least one through hole is further provided therein with at least one conductive connection unit respectively.

13. The method for manufacturing a metal-ceramic composite strip lead frame of claim 9, wherein at least one metal line is provided on the ceramic layer of the chip carrier and is connected to the chip on the chip carrier.

14. The method for manufacturing a metal-ceramic composite strip lead frame of claim 10, wherein at least one metal line is provided on the ceramic layer of the chip carrier and is connected to the chip on the chip carrier.

15. A light-emitting diode, comprising a metal-ceramic composite lead frame structure of claim 1.
